(19) United States
(12) Patent Application Publication
(10) Pub. No.: US 2025/0221104 A1
(43) Pub. Date: Jul. 3, 2025

(54) LIGHT EMITTING DIODE AND DISPLAY DEVICE INCLUDING THE SAME

(71) Applicant: LG Display Co., Ltd., Seoul (KR)

(72) Inventor: HyeongSeok KIM, Gyeonggi-do (KR)

(21) Appl. No.: 18/767,510

(22) Filed: Jul. 9, 2024

(30) Foreign Application Priority Data
Dec. 27, 2023 (KR) 10-2023-0192900

(51) Int. Cl. H01L 33/38; H01L 25/16

(52) U.S. Cl. CPC H10H 20/831; H01L 25/167

(57) ABSTRACT

A light emitting diode is provided, which comprises a first electrode disposed on a first region of a first semiconductor layer, and a magnetic substance that does not overlap an active layer and is disposed on a second region of the first semiconductor layer. In addition to, a light emitting diode is provided, which comprises a first electrode disposed on a first region of a first semiconductor layer, and a magnetic substance that is disposed on the second semiconductor layer and overlaps a second region of the first semiconductor layer.

### CROSS-REFERENCE TO RELATED APPLICATIONS

This application claims the benefit of the Korean Patent Application No. 10-2023-0192900 filed on Dec. 27, 2023, which is hereby incorporated by reference as if fully set forth herein.

### BACKGROUND

### Technical Field

The present disclosure relates to a light emitting diode and display device including the same.

### Description of the Related Art

In addition to the display screen of a television or monitor, a display device is widely used as a notebook computer, a tablet computer, a smart phone, a portable display device, and a portable information device display screen. a liquid crystal display device and an organic light emitting display device display an image using a transistor as switching elements. Since the liquid crystal display device does not use its own light emitting method, the image is displayed using light irradiated from the backlight unit disposed under the liquid crystal display panel. Since such a liquid crystal display device has a backlight unit, there is a limitation in design, and luminance and response speed may be lowered. Since the organic light emitting display device includes an organic material, it is vulnerable to moisture, and reliability and lifespan may be deteriorated.

Recently, research and development of the light emitting diode display device using light emitting diodes (LEDs) have been underway, and this light emitting diode display device is in the spotlight as next-generation displays because of their high definition and high reliability.

In order to implement a high-definition light emitting diode display device, it is necessary to apply a micro LED having a small size, and in this case, a very many light emitting diodes must be mounted on a substrate. For this purpose, an assembly method using magnetism is used. Specifically, after the electrode of the light emitting diode is formed to have magnetism, the electric field may be generated by applying a voltage to the assembly substrate. When the electric field is generated, the light emitting diode may be assembled in the groove of the assembly substrate by the magnetism of the electrode of the light emitting diode. In this case, even if a partial region of the light emitting diode is damaged, if a magnetic substance exists in the light emitting diode, the light emitting diode may be assembled to the assembly substrate. Accordingly, a problem occurs in that the assembly rate of the light emitting diode decreases.

### BRIEF SUMMARY

The present disclosure has been made in view of the above problems and it is an object of the present disclosure to provide a light emitting diodes improved with assembly rates during transfer and a display device including the same.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a light emitting diode comprising a first semiconductor layer including a first, second and third regions, an active layer exposing the first and second regions of the first semiconductor layer and covering the third region of the first semiconductor layer, a first electrode disposed on the first region of the first semiconductor layer, a magnetic substance disposed on the second region of the first semiconductor layer, and a second electrode disposed on the third region of the first semiconductor layer, and wherein the magnetic substance does not overlap with the active layer.

In addition, in accordance with an aspect of the present disclosure, the above and other objects can be accomplished by the provision of a light emitting diode comprising a first semiconductor layer including a first and second region, an active layer exposing the first region of the first semiconductor layer and covering the second region of the first semiconductor layer, a second semiconductor layer disposed on the active layer, a first electrode disposed on the first region of the first semiconductor layer, and a magnetic substance and a second electrode disposed on the second semiconductor layer, and wherein the magnetic substance and the second electrode overlap the second region of the first semiconductor layer.

### BRIEF DESCRIPTION OF THE SEVERAL VIEWS OF THE DRAWINGS

FIGS. 1A and 1B are plan views illustrating a light emitting diode according to a first embodiment of the present disclosure.

FIGS. 2A and 2B are cross-sectional views illustrating a light emitting diode according to a first embodiment of the present disclosure.

FIGS. 3A and 3B are plan views illustrating a light emitting diode according to a second embodiment of the present disclosure.

FIG. 4 is a cross-sectional view illustrating a light emitting diode according to a second embodiment of the present disclosure.

FIGS. 5A and 5B are plan views illustrating a light emitting diode according to a third embodiment of the present disclosure.

FIG. 6 is a cross-sectional view illustrating a light emitting diode according to a third embodiment of the present disclosure.

FIG. 7 is a plan view illustrating a light emitting diode according to a fourth embodiment of the present disclosure.

FIG. 8 is a cross-sectional view illustrating a light emitting diode according to a fourth embodiment of the present disclosure.

FIG. 9 is a plan view illustrating a light emitting diode according to a fifth embodiment of the present disclosure.

FIG. 10 is a cross-sectional view illustrating a light emitting diode according to a fifth embodiment of the present disclosure.

FIG. 11 is a cross-sectional view illustrating a light emitting diode according to an embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the claims are not limited by the present disclosure.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Hereinafter, the preferred embodiment of the present disclosure will be described in detail with reference to the accompanying drawings.

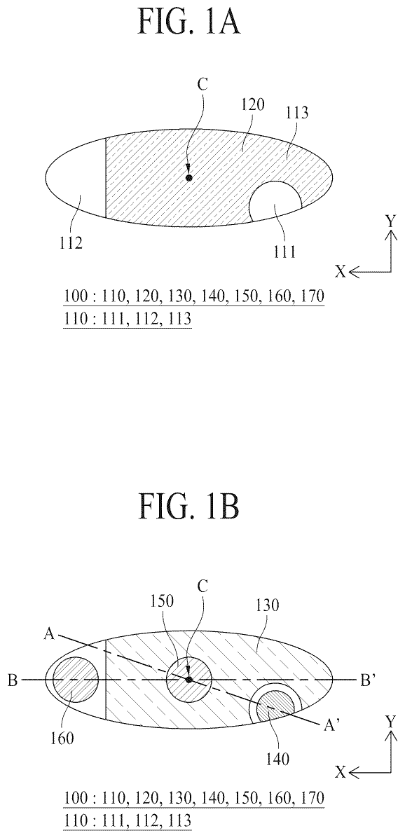

FIGS. 1A and 1B are plan views illustrating a light emitting diode 100 according to a first embodiment of the present disclosure. In FIGS. 1A and 1B, a first direction X may be a horizontal direction, or an X-axis direction. Also, a second direction Y may be a direction perpendicular to the first direction X and may be a vertical direction, or a Y-axis direction.

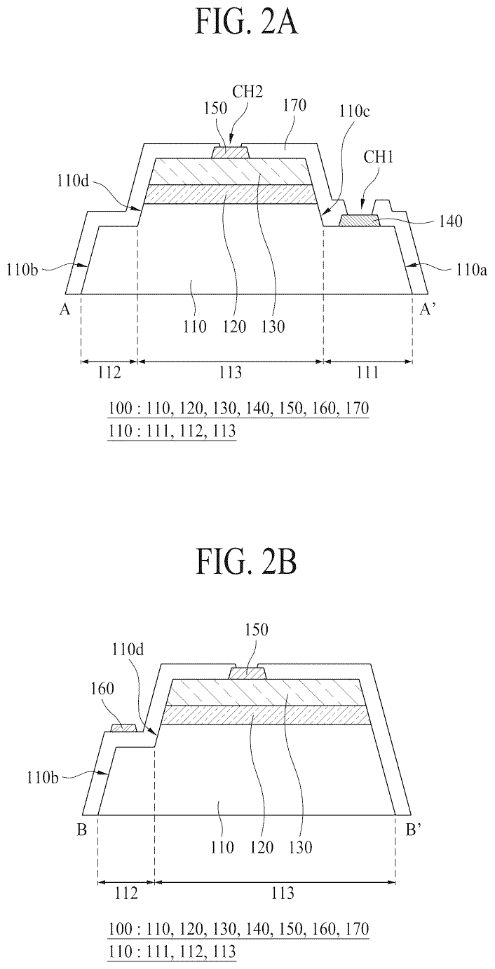

Referring to FIGS. 1A to 2B, the light emitting diode 100 may include a first semiconductor layer 110, an active layer 120, a second semiconductor layer 130, a first electrode 140, a second electrode 150, and a magnetic substance 160.

Referring to FIG. 1A, a upper surface of the first semiconductor layer 110 may be formed in an elliptical shape, but is not limited thereto. For example, the first semiconductor layer 110 may be formed in a circular shape or a polygonal shape. The first semiconductor layer 110 may provide electrons to the active layer 120. The first semiconductor layer 110 may be formed of an n-GaN-based semiconductor material such as GaN, AlGaN, InGaN, or AlInGaN. Also, Si, Ge, Se, Te, C, or the like may be used as impurities for doping the first semiconductor layer 110.

The first semiconductor layer 110 may include first to third regions 111, 112 and 113.

The first region 111 may be disposed on one side of the first semiconductor layer 110. A portion of ab edge of the first region 111 may be curved. That is, the first region 111 may be a region surrounded by a curved line formed to be concave from an edge of the first semiconductor layer 110 toward an inside of the first semiconductor layer 110 and the edge of the first semiconductor layer 110. Also, the first region 111 may be in contact with the edge of the first semiconductor layer 110. That is, a portion of the edge of the first region 111 may correspond to the edge of the first semiconductor layer 110. In FIG. 1A, when a straight line passing through the center C of the first semiconductor layer 110 and parallel to the first direction X is used as a reference line, the first region 111 is disposed below the reference line, but is not limited thereto.

The second region 112 may be formed on the other side of the first semiconductor layer 110 and may be spaced apart from the first region 111. An area of the second region 112 may be larger than an area of the first region 111, but is not limited thereto. The second region 112 may have a shape obtained by cutting a portion of the first semiconductor layer 110 in a straight line parallel to the second direction Y. As shown in FIG. 1A, when the first semiconductor layer 110 has an elliptical shape, one side of the second region 112 may be parallel to the short axis of the first semiconductor layer 110. Also, one side of the second region 112 may be disposed between the other end of the first semiconductor layer 110 and the center C.

The third region 113 may be the remaining region of the first semiconductor layer 110 except for the first and second regions 111 and 112. A boundary region of the first and third regions 111 and 113 may have a round shape. Also, A boundary region of the second and third regions 112 and 113 may have a linear shape. Also, A boundary region of the second and third regions 112 and 113 may be disposed between the other end of the first semiconductor layer 110 and the center C. A area of the third region 113 among the first to third regions 111 to 113 may be the largest.

The active layer 120 may be disposed on the first semiconductor layer 110. Also, the active layer 120 may expose the first and second regions 111 and 112 of the first semiconductor layer 110. That is, the active layer 120 may have a shape in which a partial region is concave, and may expose the first region 111. Also, the active layer 120 may cover the third region 113. That is, the active layer 120 may have a shape corresponding to that of the third region 113.

The active layer 120 may be a light emitting layer. The active layer 120 may have a multi-quantum well (MQW) structure including a well layer and a barrier layer having a higher band gap than the well layer. For example, the active layer 120 may have a multi-quantum well structure such as InGaN/GaN, but is not limited thereto.

FIG. 1B illustrates a structure in which a second semiconductor layer 130, a first electrode 140, a second electrode 150, and a magnetic substance 160 (or magnetic layer 160) are disposed on the active layer 120.

The second semiconductor layer 130 may be disposed on the active layer 120. The second semiconductor layer 130 may cover an entire upper surface of the active layer 120. That is, the second semiconductor layer 130 may have a shape corresponding to that of the active layer 120. Accordingly, the second semiconductor layer 130 may expose the first and second regions 111 and 112 of the first semiconductor layer 110.

The second semiconductor layer 130 may be formed of a p-GaN-based semiconductor material such as GaN, AlGaN, InGaN, or AlInGaN. Also, Mg, Zn, Be, or the like may be used as an impurity for doping the second semiconductor layer 130.

The first electrode 140 may be disposed on the first region 111 of the first semiconductor layer 110. An area of the first electrode 140 may be smaller than an area of the first region 111 of the first semiconductor layer 110. Also, the first electrode 140 may be formed in a shape corresponding to the shape of the first region 111. That is, a portion of an edge of the first electrode 140 may have a round shape. Also, an end of the first electrode 140 may overlap an end of the first semiconductor layer 110, but is not limited thereto.

The second electrode 150 may be disposed on the second semiconductor layer 130. The second electrode 150 may be overlap the center C of the first semiconductor layer 110. Also, the second electrode 150 may have a circular shape, but is not limited thereto.

Each of the first and second electrodes 140 and 150 may include a metal material such as Au, W, Pt, Si, Ir, Ag, Cu, Ni, Ti, or Cr, and an alloy thereof. Alternatively, each of the first and second electrodes 140 and 150 may include a transparent conductive material such as an indium tin oxide (ITO) or an indium zinc oxide (IZO).

The magnetic substance 160 may be disposed on the second region 112 of the first semiconductor layer 110. An area of the magnetic substance 160 may be smaller than the area of the second region 112 of the first semiconductor layer 110. Also, the magnetic substance 160 may be formed in a shape corresponding to a shape of the second region 112 and may be spaced apart from the first electrode 140 disposed on the first region 111. That is, a portion of an edge of the magnetic substance 160 may have a round shape.

The magnetic substance 160 may be a metal material such as iron (Fe), nickel (Ni), cobalt (Co), lead (Pb), aluminum (Al), copper (Cu), silver (Ag), gold (Au), tungsten (W), molybdenum (Mo), or the like, but is not limited thereto.

FIGS. 2A and 2B are cross-sectional views illustrating a light emitting diode 100 according to a first embodiment of the present disclosure.

FIG. 2A is a cross-sectional view illustrating the light emitting diode 100 corresponding to the line A-A′ of FIG. 1B, and FIG. 2B is a cross-sectional view illustrating the light emitting diode 100 corresponding to the line B-B′ of FIG. 1B.

As described above, the light emitting diode 100 may include the first semiconductor layer 110, the active layer 120, the second semiconductor layer 130, the first electrode 140, the second electrode 150, and the magnetic substance 160. Also, the first semiconductor layer 110 may include first to third regions 111, 112 and 113.

Referring to FIG. 2A, the first semiconductor layer 110 may include first to fourth side surfaces 110a to 110d. The first side surface 110a and the second side surface 110b may face each other, and the third side surface 110c and the fourth side surface 110d may face each other. Also, heights of the first side surface 110a and the second side surface 110b may be the same, and heights of the third side surface 110c and the fourth side surface 110d may be the same.

One side of the first region 111 may correspond to the first side surface 110a, and the other side of the first region 111 may be in contact with the third region 113. Also, one side of the second region 112 may correspond to the second side surface 110b, and the other side of the second region 112 may be in contact with the third region 113.

Among the first to third regions 111 to 113, a thickness of the third region 113 may be the greatest. That is, the third region 113 may correspond to a region protruding from the first semiconductor layer 110. Also, a height of an upper surface of the third region 113 may be higher than the heights of the first and second regions 111 and 112. Accordingly, the third side surface 110c may be in contact with an upper surface of the first region 111, and the fourth side surface 110d may be in contact with an upper surface of the second region 112.

As described above with reference to FIG. 1A, a boundary between the first and third regions 111 and 113 may have a curved shape. Specifically, the third region 113 having a protruding shape may be formed by etching a portion of first semiconductor layer 110 corresponding to the first region 111. Accordingly, the third side surface 110c may have a curved shape, and a portion where the third side surface 110c is in contact with the first region 111 may have a curved shape.

Compared with a structure in which the third side 110c is formed as a plane, when a contact portion between the third side surface 110c and the first region 111 is curved, the possibility of damage to the contact portion between the third side 110c and a top surface of the first region 111 may be reduced. Accordingly, the possibility of separation of the first region 111 from the light emitting diode 100 due to the damage may be reduced, and thus the defect rate of the light emitting diode 100 may be reduced.

The active layer 120 may be disposed on the upper surface of the third region 113 of the first semiconductor layer 110, and the second semiconductor layer 130 may be disposed on the upper surface of the active layer 120.

The first electrode 140 may be disposed on an upper surface of the first region 111 of the first semiconductor layer 110. A height of the first electrode 140 may be less than a height of the third side surface 110c. That is, the first electrode 140 may not face a side surface of the active layer 120. Also, the second electrode 150 may be disposed on an upper surface of the second semiconductor layer 130. The second electrode 150 may be overlap the third region 113 of the first semiconductor layer 110.

The light emitting diode 100 may further include a protective layer 170.

The protective layer 170 may be formed to cover top and side surfaces of the light emitting diode 100. Specifically, the protective layer 170 may cover all surfaces of the first semiconductor layer 110, the active layer 120, and the second semiconductor layer 130. Also, the protective layer 170 may cover side surfaces of the first and second electrodes 140 and 150 and expose a portion of a top surface of the first and second electrodes 140 and 150. Specifically, the protective layer 170 may expose a portion of the top surface of the first electrode 140 using a first contact hole CH1, and may expose a portion of the top surface of the second electrode 150 using a second contact hole CH2. The first and second electrodes 140 and 150 may be electrically connected to an external wire or a driving element through the first and second contact holes CH1 and CH2.

The protective layer 170 may be formed of an inorganic insulating material such as silicon oxide (SiOx), silicon nitride (SiNx), silicon oxynitride (SiOxNy).

Referring to FIG. 2B, FIG. 2B illustrates a magnetic substance 160 of the light emitting diode 100.

The magnetic substance 160 may be overlap the second region 112 of the first semiconductor layer 110. Also, the magnetic substance 160 may be disposed on the upper surface of the protective layer 170. Accordingly, the magnetic substance 160 may be electrically separated from the first semiconductor layer 110.

The sum of a thickness of the protective layer 170 and a thickness of the magnetic substance 160 may be less than a height of the fourth side surface 110d. That is, the magnetic substance 160 may not face a side surface of the active layer 120.

The magnetic substance 160 may be used in a process of assembling the light emitting diode 100 to an assembly substrate after forming the light emitting diode 100. Specifically, when an electric field is generated by applying a voltage to the assembly substrate, the light emitting diode 100 may be assembled to a groove of the assembly substrate by the magnetic substance 160. In this case, since the magnetic substance 160 is independently spaced apart from the first and second electrodes 140 and 150, the assembly rate of the light emitting diode 100 may be improved.

Specifically, when the electrode of the light emitting diode simultaneously functions as a magnetic substance, even if a part of the light emitting diode is damaged, the electrode may be disposed on the light emitting diode. In this case, the damaged light emitting diode may be assembled in a groove of an assembly substrate. Therefore, the damaged light emitting diode may emit unstable light, resulting in color mixing, or a short may occur inside the light emitting diode.

However, according to the present disclosure, it is disclosed that the first electrode 140 is disposed on one side of the light emitting diode 100 and the magnetic substance 160 is disposed on the other side. Accordingly, even if one of the first electrode 140 and the magnetic body 160 is damaged, the damage of the light emitting diode 100 may be detected.

Specifically, when the first electrode 140 of the light emitting diode 100 is damaged, the damaged light emitting diode 100 may be assembled to the assembly substrate by the magnetic substance 160. However, since the light emitting diode 100 does not emit light due to damage to the first electrode 140, the damaged light emitting diode 100 may be detected. Also, when the magnetic substance 160 of the light emitting diode 100 is damaged, since the magnetic body 160 does not exist in the light emitting diode 100, the damaged light emitting diode 100 may not be assembled to the assembly substrate. Accordingly, the damaged light emitting diode 100 may be detected.

Therefore, since the possibility of detecting the damaged light emitting diode 100 increases, there is an effect of improving the assembly rate of the light emitting diode 100.

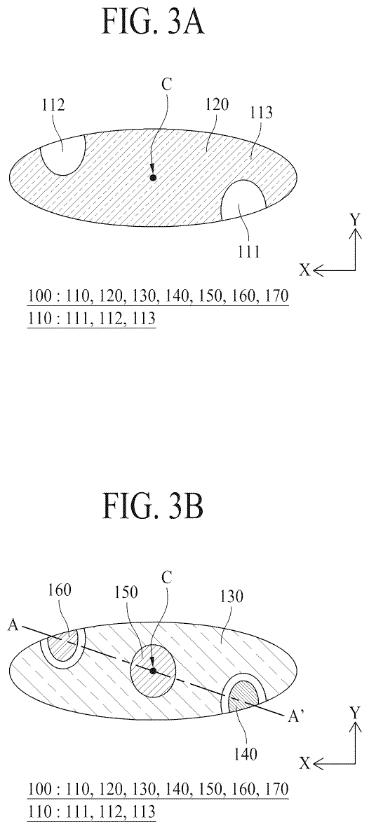

FIGS. 3A and 3B are plan views illustrating a light emitting diode 100 according to a second embodiment of the present disclosure.

Compared with FIGS. 1A and 1B, substantially the same structure is disclosed except for the structures of the first semiconductor layer 110 and the magnetic body 160. Accordingly, the same reference numerals are used for the same components as those of the light emitting diode 100 shown in FIGS. 1A and 1B, and repeated descriptions are omitted.

As described above, the first semiconductor layer 110 may include first to third regions 111, 112, and 113.

The first region 111 described in FIG. 3A may have the same shape and characteristics as the first region 111 described in FIG. 1A. That is, the first region 111 may be a region surrounded by a curved line formed to be concave from the edge of the first semiconductor layer 110 toward the inside of the first semiconductor layer 110.

The second region 112 may be disposed on the other side of the first semiconductor layer 110 and may be spaced apart from the first region 111. Like the first region 111, the second region 112 may be a region surrounded by a curved line formed to be concave from the edge of the semiconductor layer 110 toward the inside of the first semiconductor layer 110 and an edge of the first semiconductor layer 110. Also, the second region 112 may have the same area as the first region 111, but is not limited thereto.

A portion of an edge of the second region 112 may be curved, and may be spaced apart from the first region 111 at a position farthest from the first region 111. For example, referring to FIG. 3A, when a straight line parallel to the first direction X passing through the center C of the first semiconductor layer 110 is used as a reference line, the first region 111 may be disposed below the reference line, and the second region 112 may be disposed above the reference line. Also, when a straight line parallel to the second direction Y while passing through the center C of the first semiconductor layer 110 is used as a reference line, the first region 111 may be formed on the right side of the reference line, and the second region 112 may be formed on the left side of the reference line.

The active layer 120 may be disposed on the first semiconductor layer 110 and may have a shape corresponding to that of the third region 113. That is, the active layer 120 may have a shape in which a partial region is concave, and may expose the first and second regions 111 and 112.

FIG. 3B illustrates a structure in which a second semiconductor layer 130, a first electrode 140, a second electrode 150, and a magnetic substance 200 are disposed on the active layer 120.

As described above, the second semiconductor layer 130 may have a shape corresponding to that of the active layer 120. Furthermore, the first electrode 140 may be disposed on the first region 111 of the first semiconductor layer 110, the second electrode 150 may be disposed on the second semiconductor layer 130, and the magnetic substance 160 may be formed on the second region 112 of the first semiconductor layer 110. Furthermore, the first electrode 140, the second electrode 150, and the magnetic body 160 may be disposed on any one straight line passing through the center C of the first semiconductor layer 110.

The area of the magnetic substance 160 may be smaller than the area of the second region 112 of the first semiconductor layer 110. Also, the magnetic substance 160 may be formed in the same shape as the first electrode 140, but is not limited thereto.

As compared with the first embodiment shown in FIGS. 1A and 1B, the second embodiment may increase the area of the third region 113 by reducing the area of the second region 112 of the first semiconductor layer 110. That is, compared to the first embodiment, the second embodiment may increase the area of the active layer 113. Accordingly, the second embodiment may further increase the light emission area.

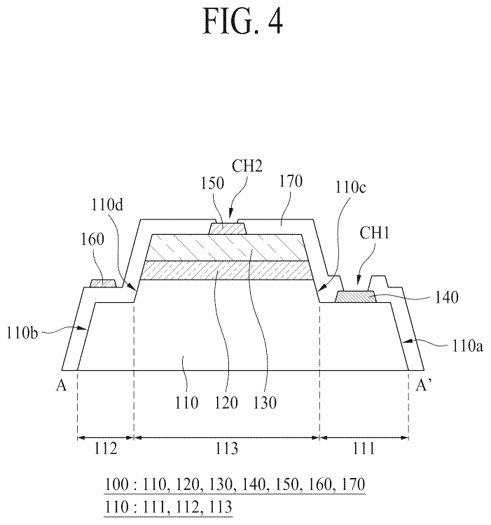

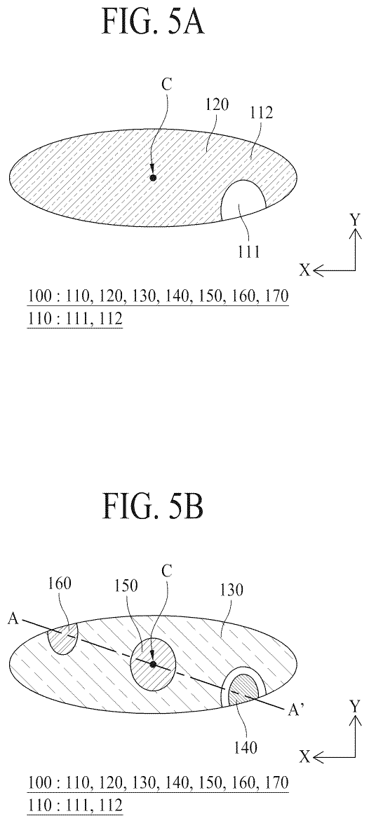

FIG. 4 is a cross-sectional view illustrating a light emitting diode 100 according to a second embodiment of the present disclosure. That is, FIG. 4 is a cross-sectional view of the light emitting diode 100 corresponding to the line A-A′ of FIG. 3B.

As described above, the light emitting diode 100 may include a first semiconductor layer 110, an active layer 120, a second semiconductor layer 130, a first electrode 140, a second electrode 150, a magnetic substance 160, and a protective layer 170.

The first electrode 140 may be disposed on an upper surface of the first region 111 of the first semiconductor layer 110, and a height of the first electrode 140 may be less than a height of the third side surface 110c. Furthermore, the magnetic substance 160 may be overlap the second region 112 of the first semiconductor layer 110. Furthermore, the magnetic substance 160 may be disposed on an upper surface of the protective layer 170. Accordingly, the magnetic substance 160 may be electrically separated from the first semiconductor layer 110.

As described above with reference to FIG. 2A, the first embodiment discloses a reduction in the possibility of damage to a portion where the third side 110c is in contact with the first region 111 by forming a curved portion, such that the third side 110c is in contact with the first region 111. In the second embodiment, similar to the structure of the third side 110c and the first region 111, the contact portion between the fourth side 110d and the second region 112 is formed in a curved shape. Therefore, the possibility of damage to a portion where the fourth side surface 110d and the upper surface of the second region 112 are in contact with each other may be reduced. Accordingly, the second embodiment may further prevent the light emitting diode 100 from being damaged.

FIGS. 5A and 5B are plan views illustrating a light emitting diode according to a third embodiment of the present disclosure.

Compared with FIGS. 3A and 3B, the third embodiment discloses substantially the same structure except for the structures of the first semiconductor layer 110 and the magnetic body 160. Accordingly, the same reference numerals are used for the same components as those of the light emitting diode 100 illustrated in FIGS. 3A and 3B, and repeated descriptions are omitted.

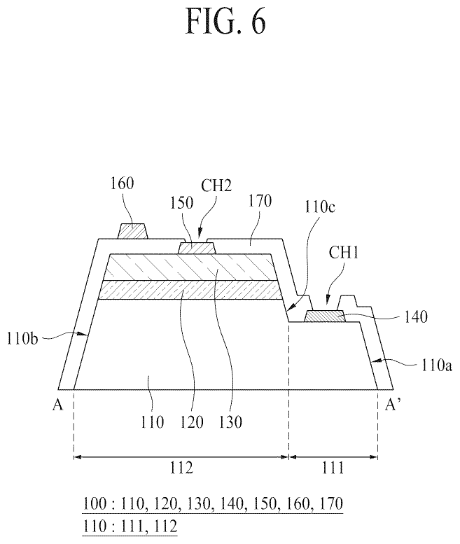

Referring to FIGS. 5A to 6, the first semiconductor layer 110 may include first and second regions 111 and 112.

The first region 111 described in FIG. 5A may have the same shape and characteristics as the first region 111 described in FIG. 3A. That is, the first region 111 may be a region surrounded by a curve formed concave from the edge of the first semiconductor layer 110 toward the inside of the first semiconductor layer 110 and the edge of the first semiconductor layer 110.

The second region 112 may be a region other than the first region 111 in the first semiconductor layer 110. The boundary region between the first and second regions 111 and 112 may have a round shape. An area of the second region 112 may be larger than an area of the first region 111.

The active layer 120 may be disposed on the first semiconductor layer 110. Also, the active layer 120 may expose the first region 111 of the first semiconductor layer 110. That is, the active layer 120 may have a shape in which a partial region is concave, and may expose the first region 111. Also, the active layer 120 may cover the second region 112. That is, the active layer 120 may have a shape corresponding to that of the second region 112.

FIG. 5B illustrates a structure in which a second semiconductor layer 130, a first electrode 140, a second electrode 150, and a magnetic body 200 are disposed on the active layer 120.

The second semiconductor layer 130 may have a shape corresponding to that of the active layer 120. Also, the first electrode 140 may be disposed on the first region 111 of the first semiconductor layer 110, and the second electrode 150 and the magnetic substance 160 may be disposed on the second semiconductor layer 130. Also, the first electrode 140, the second electrode 150, and the magnetic substance 160 may be spaced apart from each other, and the first electrode 140, the second electrode 150, and the magnetic substance 160 may be disposed on any one straight line passing through the center C of the first semiconductor layer 110, but are not limited thereto.

The magnetic substance 160 may be disposed far from the first electrode 140. For example, referring to FIG. 5B, when a straight line parallel to the first direction X passes through the center C of the first semiconductor layer 110 as a reference line, the first electrode 140 may be disposed below the reference line, and the magnetic substance 160 may be disposed above the reference line. Also, when a straight line parallel to the second direction Y while passing through the center C of the first semiconductor layer 110 is used as a reference line, the first electrode 140 may be disposed on the right side of the reference line, and the magnetic substance 160 may be disposed on the left side of the reference line. Also, the magnetic substance 160 may be disposed in the same shape as the first electrode 140, but is not limited thereto.

Compared with the second embodiment shown in FIGS. 3A and 3B, the third embodiment discloses forming a magnetic substance 160 on the second semiconductor layer 130. Accordingly, the area for arranging the magnetic substance 160 on the first semiconductor layer 110 may be omitted, and thus the area of the active layer 120 may be further increased. Accordingly, the third embodiment may further increase the light emitting area.

FIG. 6 is a cross-sectional view illustrating a light emitting diode 100 according to a third embodiment of the present disclosure. That is, FIG. 6 is a cross-sectional view of the light emitting diode 100 corresponding to the line A-A′ of FIG. 5B.

As described above, the light emitting diode 100 may include a first semiconductor layer 110, an active layer 120, a second semiconductor layer 130, a first electrode 140, a second electrode 150, a magnetic substance 160, and a protective layer 170. Also, the first semiconductor layer 110 may include first and second regions 111 and 112.

Referring to FIG. 6, the first semiconductor layer 110 may include first to third side surfaces 110a to 110c. The first side surface 110a and the second side surface 110b may face each other. Also, the heights of the first side surface 110a and the second side surface 110b may be the same.

One side of the first region 111 may correspond to the first side surface 110a, and the other side of the first region 111 may be in contact with the second region 112. Also, one side of the second region 112 may correspond to the second side surface 110b, and the other side of the second region 112 may be in contact with the first region 111.

The thickness of the second region 112 may be greater than the thickness of the first region 111. That is, the second region 112 may correspond to a region protruding from the first semiconductor layer 110. Also, the height of the upper surface of the second region 112 may be higher than the height of the first region 111. Accordingly, the third side surface 110c may be in contact with the upper surface of the first region 111.

As described above with reference to FIG. 5A, the boundary between the first and second regions 111 and 112 may have a curved shape. Accordingly, the third side surface 110c may have a curved shape, and a portion where the third side surface 110c is in contact with the first region 111 may have a curved shape. Accordingly, the possibility that the first region 111 is separated from the light emitting diode 100 due to damage may be reduced, and thus the defect rate of the light emitting diode 100 may be reduced.

The active layer 120 may be disposed on the upper surface of the third region 113 of the first semiconductor layer 110, and the second semiconductor layer 130 may be disposed on the upper surface of the active layer 120.

The first electrode 140 may be disposed on an upper surface of the first region 111 of the first semiconductor layer 110, and the second electrode 150 may be disposed on an upper surface of the second semiconductor layer 130. The second electrode 150 may be overlap the second region 112 of the first semiconductor layer 110. Also, the protective layer 170 may be disposed to cover an upper surface and a side surface of the light emitting diode 100.

The magnetic substance 160 may be disposed on an upper surface of the protective layer 170. Accordingly, the magnetic substance 160 may be electrically separated from the first and second semiconductor layers 110 and 130. Also, the magnetic substance 160 may be overlap the second region 112, the active layer 120, and the second semiconductor layer 130 of the first semiconductor layer 110. That is, the magnetic substance 160 may be disposed at a position higher than the first and second electrodes 140 and 150.

Compared with the second embodiment shown in FIG. 4, the third embodiment discloses forming the magnetic substance 160 on the uppermost end of the light emitting diode 100. That is, compared with the second embodiment including the magnetic substance 160 disposed on the step region of the first semiconductor layer 110, the step region for arranging the magnetic body 160 may be omitted in the third embodiment. Accordingly, since the step region of the first semiconductor layer 110 may be minimized, the possibility of damage to the light emitting diode 100 may be further reduced.

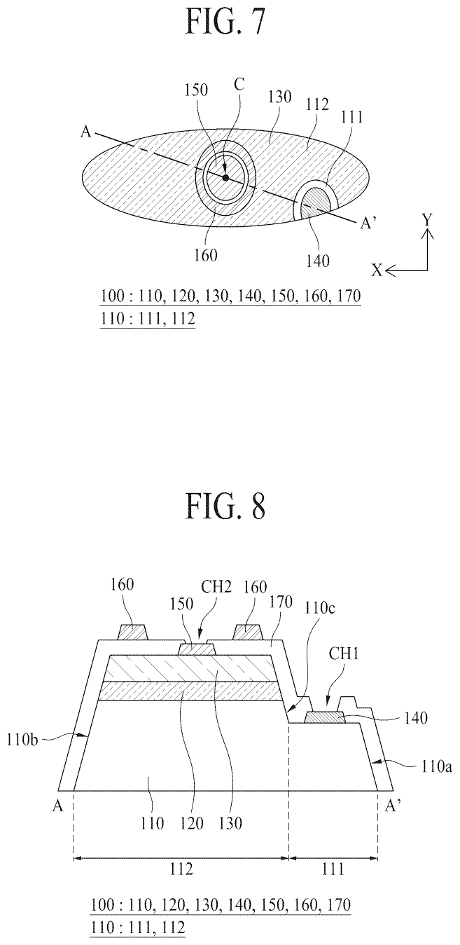

FIG. 7 is a plan view illustrating a light emitting diode according to a fourth embodiment of the present disclosure. Compared with FIGS. 5A and 5B, substantially the same structure is disclosed except for the structure of the magnetic substance 160. Accordingly, the same reference numerals are used for elements that are the same as those of the light emitting diode 100 illustrated in FIGS. 5A and 5B, and repeated descriptions are omitted.

Referring to FIG. 7, the magnetic substance 160 may be disposed on the second semiconductor layer 130. Also, the magnetic substance 160 may be formed in a shape surrounding the second electrode 150. Also, the magnetic substance 160 may have a circle shape or a ring shape, and a partial region of the circle or a partial region of the ring may be spaced apart from each other. As illustrated in FIG. 7, when the second electrode 150 has a circular shape, the magnetic substance 160 may have a ring shape having a constant radius from the center of the second electrode 150. Also, the magnetic substance 160 may be spaced apart from the second electrode 150.

Since the magnetic substance 160 according to the fourth embodiment is disposed at the center of the light emitting diode 100, the light emitting diode 100 may be more stably assembled in the process of assembling the light emitting diode 100 to the assembly substrate. Also, compared to a structure in which the magnetic substance 160 is formed to be biased to one side rather than the center of the light emitting diode 100, light generated in the active layer 120 may be more uniformly emitted.

FIG. 8 is a cross-sectional view illustrating a light emitting diode according to a fourth embodiment of the present disclosure. That is, FIG. 8 is a cross-sectional view of the light emitting diode 100 corresponding to the line A-A′ of FIG. 7.

As described above, the light emitting diode 100 may include a first semiconductor layer 110, an active layer 120, a second semiconductor layer 130, a first electrode 140, a second electrode 150, a magnetic substance 160, and a protective layer 170. Also, the first semiconductor layer 110 may include first and second regions 111 and 112.

Referring to FIG. 8, the magnetic substance 160 may be disposed on an upper surface of the protection layer 170. Accordingly, the magnetic substance 160 may be electrically separated from the first and second semiconductor layers 110 and 130. Furthermore, the magnetic substance 160 may be overlap the second region 112 of the first semiconductor layer 110, the active layer 120, and the second semiconductor layer 130. That is, the magnetic substance 160 may be disposed at a position higher than the first and second electrodes 140 and 150.

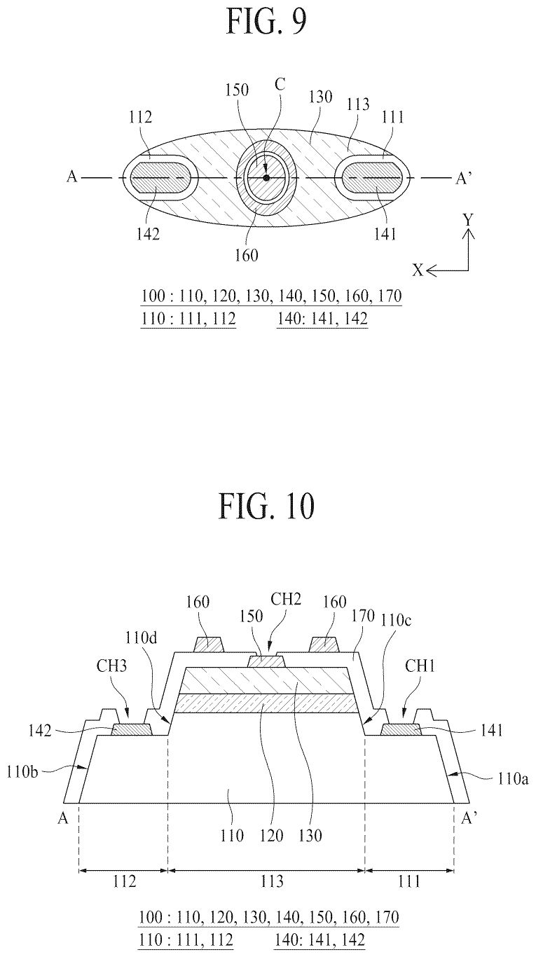

FIG. 9 is a plan view illustrating a light emitting diode according to a fifth embodiment of the present disclosure. Compared with FIG. 7, substantially the same structure is disclosed except for the structures of the first semiconductor layer 110 and the first electrode 140. Accordingly, the same reference numerals are used for the same elements as those of the light emitting diode 100 illustrated in FIG. 7, and repeated descriptions are omitted.

Referring to FIGS. 9 to 10, the first semiconductor layer 110 may include first to third regions 111 to 113.

The first region 111 may be disposed on one side of the first semiconductor layer 110, and the second region 112 may be disposed on the other side of the first semiconductor layer 110. Also, the third region 113 may be a region excluding the first and second regions 111 and 112 from the first semiconductor layer 110.

The first and second regions 111 and 112 may be regions surrounded by a curve formed concave from the edge of the first semiconductor layer 110 toward the inside of the first semiconductor layer 110. The first and second regions 111 and 112 may be spaced apart from each other. Also, when a straight line parallel to the first direction X passing through the center C of the first semiconductor layer 110 is used as a reference line, the first and second regions 111 and 112 may be disposed on the reference line.

The first electrode 140 may include first and second sub electrodes 141 and 142. The first sub electrode 141 may be disposed in the first region 111 of the first semiconductor layer 110, and the second sub electrode 142 may be disposed in the second region 112 of the first semiconductor layer 110.

The first sub-electrode 141 may be formed in a shape corresponding to the first region 111 of the first semiconductor layer 110, and the second sub-electrode 142 may be formed in a shape corresponding to the second region 112 of the first semiconductor layer 110. That is, a part of the edges of each of the first and second sub-electrodes 141 and 142 may have a round shape.

The ends of each of the first and second sub electrodes 141 and 142 may be spaced apart from the ends of the first semiconductor layer 110, but are not limited thereto. Furthermore, the first and second sub electrodes 141 and 142 may be formed of the same material. Furthermore, as illustrated in FIG. 9, the first and second sub electrodes 141 and 142 may have the same shape, but may also have different shapes.

When a straight line passing through the center C of the first semiconductor layer 110 and parallel to the first direction X is used as a reference line, the light emitting diode 100 may have a symmetrical structure with respect to the reference line. Also, when a straight line passing through the center C of the first semiconductor layer 110 and parallel to the second direction Y is used as a reference line, the light emitting diode 100 may have a symmetrical structure with respect to the reference line.

FIG. 10 is a cross-sectional view illustrating a light emitting diode according to a fifth embodiment of the present disclosure. That is, FIG. 10 is a cross-sectional view of the light emitting diode 100 corresponding to the line A-A′ of FIG. 9.

As described above, the light emitting diode 100 may include a first semiconductor layer 110, an active layer 120, a second semiconductor layer 130, a first electrode 140, a second electrode 150, a magnetic substance 160, and a protective layer 170.

Referring to FIG. 10, the first semiconductor layer 110 may include first to fourth side surfaces 110a to 110d. The first side surface 110a and the second side surface 110b may face each other to be spaced apart from each other, and the third side surface 110c and the fourth side surface 110d may face each other to be spaced apart from each other. Also, the first side surface 110a and the second side surface 110b may have the same height, and the third side surface 110c and the fourth side surface 110d may have the same height.

As described above, the first semiconductor layer 110 may include first to third regions 111 to 113. One side of the first region 111 may correspond to the first side surface 110a, and the other side of the first region 111 may be in contact with the third region 113. Also, one side of the second region 112 may correspond to the second side surface 110b, and the other side of the second region 112 may be in contact with the third region 113.

The thickness of the third region 113 among the first to third regions 111 to 113 may be the greatest. That is, the third region 113 may correspond to the region protruding from the first semiconductor layer 110.

The active layer 120 may be disposed on the upper surface of the third region 113 of the first semiconductor layer 110, and the second semiconductor layer 130 may be disposed on the upper surface of the active layer 120.

The first electrode 140 may be disposed on an upper surface of the first semiconductor layer 110. As described above, the first electrode 140 may include first and second sub electrodes 141 and 142.

The first sub electrode 141 may be disposed on the upper surface of the first region 111 of the first semiconductor layer 110, and the second sub electrode 142 may be disposed on the upper surface of the second region 112 of the first semiconductor layer 110. The height of the first sub electrode 141 may be less than the height of the third side surface 110c, and the height of the second sub electrode 142 may be less than the height of the fourth side surface 110d. That is, the first and second sub electrodes 141 and 142 may not face the side surface of the active layer 120.

The second electrode 150 may be disposed on an upper surface of the second semiconductor layer 130. The second electrode 150 may be overlap the third region 113 of the first semiconductor layer 110.

The protective layer 170 may be formed to cover the top and side surfaces of the light emitting diode 100. In detail, the protective layer 170 may cover all surfaces of the first semiconductor layer 110, the active layer 120, and the second semiconductor layer 130. Also, the protective layer 170 may cover the side surfaces of the first and second electrodes 140 and 150 and expose a partial region of the top surface.

Specifically, the protective layer 170 may expose a portion of the upper surface of the first sub-electrode 141 using the first contact hole CH1, and may expose a portion of the upper surface of the second sub-electrode 142 using the third contact hole CH3. Also, the protective layer 170 may expose a portion of the upper surface of the second electrode 150 using the second contact hole CH2. The first and second electrodes 140 and 150 may be electrically connected to an external wire or a driving element using the first to third contact holes CH1-CH3.

In this case, a fifth embodiment of the present disclosure discloses a structure in which the first electrode 140 includes first and second sub electrodes 141 and 142. Accordingly, even if any one of the first and second sub electrodes 141 and 142 is damaged, the light emitting diode 100 may be driven using the other one sub electrode.

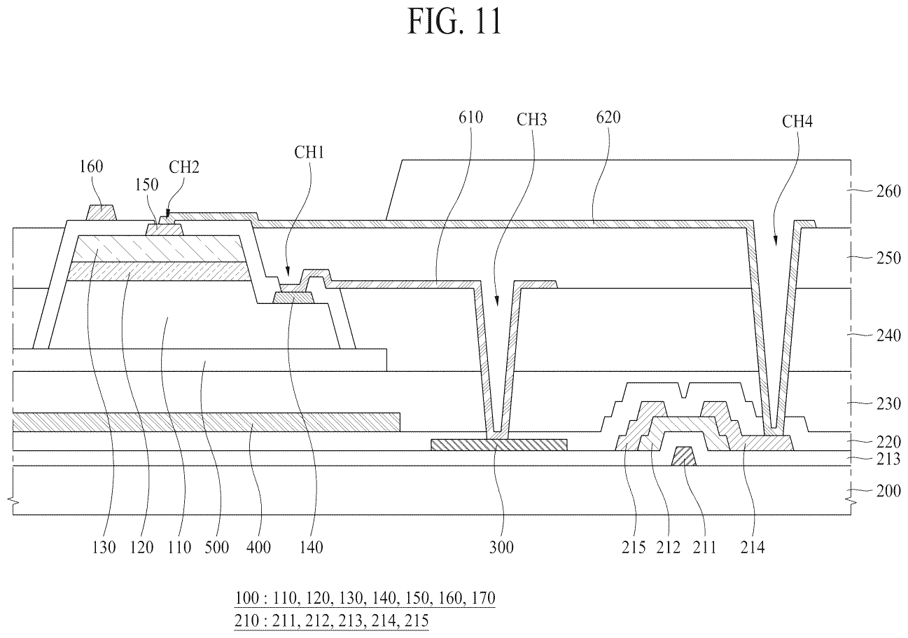

FIG. 11 is a cross-sectional view illustrating a display device according to an embodiment of the present disclosure. FIG. 11 illustrates any one pixel.

Referring to FIG. 11, a pixel according to an embodiment of the present disclosure may include a light emitting diode 100, a substrate 200, a thin film transistor 210, an interlayer insulating layer 220, a passivation layer 230, a first planarization layer 240, a second planarization layer 250, a bank 260, a common voltage line 300, a reflective layer 400, an adhesive layer 500, and a connection electrode 600.

The light emitting diode 100 may have the structure of any one of the light emitting diodes 100 described in FIGS. 1 to 10. FIG. 10 discloses the structure of the light emitting diode 100 of a third embodiment illustrated in FIG. 6.

Although FIG. 10 shows a structure in which the light emitting diode 100 includes the magnetic substance 160, it is not limited thereto. For example, the magnetic substance 160 may be removed after the light emitting diode 100 is transferred onto the substrate 200. According to the present disclosure, the magnetic substance 160 may be removed without damage to the light emitting diode 100, since the magnetic substance 160 is formed on the protective layer 170 and separated from the first and second electrodes 140 and 150.

The substrate 200 may be formed of glass or plastic, but is not limited thereto. The display device according to an embodiment of the present disclosure may be formed in a top emission type in which emitted light is emitted upward. Accordingly, not only a transparent material but also an opaque material may be used as the material of the substrate 200.

The thin film transistor 210 may be disposed on the substrate 200. The thin film transistor 210 may include a gate electrode 211, a semiconductor layer 212, a gate insulation layer 213, a source electrode 214, and a drain electrode 215.

The gate electrode 211 of the thin film transistor 210 may be disposed on the substrate 200. Also, the semiconductor layer 212 may be disposed on the gate electrode 211. The semiconductor layer 212 may include a poly-silicon semiconductor or an oxide semiconductor. Also, when the semiconductor layer 212 includes an oxide semiconductor, the semiconductor layer 212 may be include at least one oxide of IGZO (indium-gallium-zinc-oxide), IZO (indium-zinc-oxide), IGTO (indium-gallium-tin-oxide), and IGO (indium-gallium-oxide).

For insulating the gate electrode 211 and the semiconductor layer 212, the gate insulation layer 213 may be disposed between the gate electrode 211 and the semiconductor layer 212. The gate insulation layer 213 may be formed of a single layer of silicon nitride (SiNx) or silicon oxide (SiOx), or multiple layers thereof. Also, FIG. 11 discloses a bottom gate structure in which a semiconductor layer 212 is formed on the gate electrode 211, but is not limited thereto. For example, the top gate structure in which the gate electrode 211 is formed on the semiconductor layer 212 may be disclosed.

The source electrode 214 and the drain electrode 215 may be disposed on the semiconductor layer 212 while facing each other.

The common voltage line 300 may be disposed on the gate insulation layer 213. The common voltage line 300 may apply a common voltage to the light emitting diode 100. Also, the common voltage line 300 may be formed of the same material as the source electrode 214 and the drain electrode 215, but is not limited thereto.

The interlayer insulating layer 220 may be disposed on the source electrode 214, the drain electrode 215, and the common voltage line 300. A contact hole exposing portions of the source electrode 214 and common voltage line 300 may be formed in the interlayer insulating layer 220. Also, the interlayer insulating layer 220 may be formed of an inorganic insulating material such as silicon oxide (SiOx), silicon nitride (SiNx), silicon oxynitride (SiOxNy).

The reflective layer 400 may be disposed on the interlayer insulating layer 220. The reflective layer 400 may reflect the light emitted from the light emitting diode 100 toward the substrate 200 to an upper portion of the display device. Also, the reflective layer 400 may be formed of a metal material having a high reflectivity.

The passivation layer 230 may be disposed on the thin film transistor 210 and the reflective layer 400. The passivation layer 230 may compensate for a step difference caused by the thin film transistor 210 and the reflective layer 400 to form an upper region over the thin film transistor 210 to be flat. Also, the passivation layer 230 may be formed of an organic insulating material such as an acrylic resin, an epoxy resin, a phenolic resin, a polyamide resin, or a polyimide resin.

The adhesive layer 500 may be disposed on the passivation layer 230. The adhesive layer 500 may be overlap the reflective layer 400. Also, the adhesive layer 500 may fix the light emitting diode 100. Also, the adhesive layer 500 may be formed of a thermal curing material or a photocurable material, but is not limited thereto.

The first planarization layer 240 may be disposed on the interlayer insulating layer 220. The first planarization layer 240 may be formed to surround a portion of the side surface of the light emitting diode 100. Also, the first planarization layer 240 may expose the upper surface of the first electrode 140 of the light emitting diode 100. That is, the height of the upper surface of the first planarization layer 240 may be lower than the height of the upper surface of the first electrode 140 of the light emitting diode 100.

The first planarization layer 240 may be formed of an organic insulating material such as an acrylic resin, an epoxy resin, a phenolic resin, a polyamide resin, or a polyimide resin.

The first connection electrode 610 may be disposed on the first planarization layer 240. The first connection electrode 610 may be electrically connected to the common voltage line 300 using a third contact hole CH3 formed in the interlayer insulating layer 220, the passivation layer 230, and the first planarization layer 240. The first connection electrode 210 may include a metallic material such as Au, W, Pt, Si, Ir, Ag, Cu, Ni, Ti, or Cr, and an alloy thereof. Alternatively, the first connection electrode 210 may include a transparent conductive material such as an indium tin oxide (ITO) or an indium zinc oxide (IZO).

The second planarization layer 250 may be disposed on the first planarization layer 240. The second planarization layer 250 may be formed to surround the remaining area of the side surface of the light emitting diode 100, which is not covered by the first planarization layer 240. Also, the second planarization layer 250 may fill the inside of the third contact hole CH3 and expose the upper surface of the second electrode 150 of the light emitting diode 100. That is, the height of the upper surface of the second planarization layer 250 may be lower than the height of the upper surface of the second electrode 150 of the light emitting diode 100. The second planarization layer 250 may be formed of the same material as the first planarization layer 240, but is not limited thereto.

The second connection electrode 620 may be disposed on the second planarization layer 250. The second connection electrode 620 may be electrically connected to the source electrode 214 of the thin film transistor 210 using a fourth contact hole CH4 formed in the interlayer insulating layer 220, the passivation layer 230, the first planarization layer 240, and the second planarization layer 250. The second connection electrode 620 may be made of the same material as the first connection electrode 610, but is not limited thereto.

Accordingly, different voltage levels applied to each of the source electrode 214 of the thin film transistor 210 and the common voltage line 300 are transmitted to the first and second electrodes 140 and 150 using the first and second connection electrodes 610 and 620, so that the light emitting diode 100 may emit light.

FIG. 11 discloses that the thin film transistor 210 is spaced apart from the light emitting diode 100, but is not limited thereto. For example, the thin film transistor 210 and the light emitting diode 100 may be disposed to vertically overlap each other.

The bank 260 may be disposed on the second planarization layer 250. The bank 260 may fill an interior of the fourth contact hole CH4. Also, the bank 260 may be spaced apart from the light emitting diode 100. The bank 260 may be formed of an organic insulating material such as acrylic resin, epoxy resin, phenolic resin, polyamide resin, polyimide resin, or polyimide resin.

According to the present disclosure, the following advantageous effects may be obtained.

According to the present disclosure, the plurality of light conversion layers may be formed so that light efficiency may be improved, and reflectance due to external light may be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the accompanying claims is not defined by the present disclosure and it is intended that all variations or modifications derived from the meaning, scope and equivalent concept of the claims fall within the scope of the claims.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting diode comprising:
a first semiconductor layer including a first region, a second region, and a third region;
an active layer disposed on the third region of the first semiconductor layer, the active layer being absent from the first and second regions of the first semiconductor layer;
a first electrode disposed on the first region of the first semiconductor layer;
a magnetic layer disposed on the second region of the first semiconductor layer; and
a second electrode disposed on the third region of the first semiconductor layer,
wherein the magnetic layer does not overlap the active layer.

2. The light emitting diode of claim 1, wherein at least one of a boundary between the first region and the third region and a boundary between the second region and the third region is curved.

3. The light emitting diode of claim 2, wherein the boundary between the first region and the third region and the boundary between the second region and the second region are both curved.

4. The light emitting diode of claim 1, wherein the magnetic layer is not in direct contact with the first semiconductor layer.

5. The light emitting diode of claim 1, further comprising:
a protective layer disposed between the second region of the first semiconductor layer and the magnetic layer,
wherein the protective layer covers a portion of the first electrode and a portion of the second electrode.

6. The light emitting diode of claim 1, wherein the third region includes a first side and a second side opposite to the first side, and
the first region is disposed on the first side of the third region,
the second region is disposed on the second side of the third region, and
the first and second regions are spaced apart from each other.

7. The light emitting diode of claim 1, wherein heights of the first and second regions are the same, and
a height of the third region is greater than the heights of the first and second regions.

8. The light emitting diode of claim 1, further comprising:
a second semiconductor layer disposed on the active layer,
wherein the magnetic layer is disposed on the second semiconductor layer.

9. The light emitting diode of claim 1, wherein the magnetic layer is spaced apart from the first and second electrodes.

10. A light emitting diode, comprising:
a first semiconductor layer including a first region and a second region;
an active layer disposed on the second region of the first semiconductor layer, the active layer being absent from the first region of the first semiconductor layer;
a second semiconductor layer disposed on the active layer;
a first electrode disposed on the first region of the first semiconductor layer;
a magnetic layer disposed on the second semiconductor layer; and
a second electrode disposed on the second semiconductor layer,
wherein the magnetic layer and the second electrode overlap the second region of the first semiconductor layer.

11. The light emitting diode of claim 10, wherein a boundary between the first region and the second region is curved.

12. The light emitting diode of claim 10, wherein the magnetic layer is not in contact with the first and second semiconductor layers.

13. The light emitting diode of claim 10, further comprising:
a protective layer disposed between the second semiconductor layer and the magnetic layer,
wherein the protective layer covers a portion of the first electrode and a portion of second electrode.

14. The light emitting diode of claim 10, wherein the first electrode, the second electrode, and the magnetic layer are disposed on a common straight axis, and
the second electrode is disposed between the first electrode and the magnetic layer.

15. The light emitting diode of claim 14, wherein the magnetic layer is spaced apart from the second electrode and surrounds the second electrode.

16. The light emitting diode of claim 15, wherein the first semiconductor layer further includes a third region,
the active layer being absent from the third region,
the first electrode including first and second sub electrodes, and
the first sub electrode is disposed on the first region, and the second sub electrode is disposed on the third region.

17. A display device comprising:
a common voltage line and a thin film transistor disposed on a substrate;
an insulating layer disposed on the common voltage line and the thin film transistor; and
a light emitting diode disposed on the insulating layer,
wherein the light emitting diode includes:
a first semiconductor layer including a first region, a second region and a third region;
an active layer disposed on the third region of the first semiconductor layer, the active layer being absent from the first and second regions of the first semiconductor layer;
a first electrode disposed on the first region of the first semiconductor layer;
a magnetic layer disposed on the second region of the first semiconductor layer; and
a second electrode disposed on the third region of the first semiconductor layer,
wherein the magnetic layer does not overlap the active layer, and
wherein the first electrode of the light emitting diode is electrically connected to the common voltage line through a first connection electrode, and
the second electrode of the light emitting diode is electrically connected to the thin film transistor through a second connection electrode.

18. The display device of claim 17, further comprising:
a first planarization layer disposed on the insulating layer and surrounding a first portion of a side surface of the light emitting diode; and
a second planarization layer disposed on the first planarization layer and surrounding a remaining second portion of the side surface of the light emitting diode,
wherein the first connection electrode is disposed on the first planarization layer, and
the second connection electrode is disposed on the second planarization layer.
